(19) United States
(12) Patent Application Publication
(10) Pub. No.: US 2018/0097137 A1
(43) Pub. Date: Apr. 5, 2018

(54) HIGH VOLTAGE PHOTOVOLTAICS

(71) Applicant: INTERNATIONAL BUSINESS MACHINES CORPORATION, Armonk, NY (US)

(72) Inventors: Stephen W. Bedell, Wappingers Falls, NY (US); Ning Li, White Plains, NY (US); Devendra K. Sadana, Pleasantville, NY (US); Ghavam G. Shahidi, Pound Ridge, NY (US)

(21) Appl. No.: 15/285,882

(22) Filed: Oct. 5, 2016

(51) Int. Cl. H01L 31/075; H01L 31/068; H01L 31/028; H01L 31/0304; H01L 31/0352

(52) U.S. Cl. CPC H01L 31/075; H01L 31/068; H01L 31/035236; H01L 31/03044; H01L 31/0304; H01L 31/028

(57) ABSTRACT

A photovoltaic device includes a substrate and a P-type layer having a first electrode formed on a surface of the P-type layer. An N-type layer has a second electrode formed on a surface of the N-type layer. The P-type layer and the N-type are formed from a common base material. The base material includes a bandgap of at least 2 electron-volts such that a potential across the first and second electrodes is greater than 2 volts when the device is exposed to light.

### BACKGROUND

### Technical Field

The present invention generally relates to photovoltaic devices, and more particularly to devices for generating high voltage for powering electronic devices including devices employed for Internet of things (IoT) applications.

### Description of the Related Art

Remote power sources are needed for Internet of things (IoT) applications and other portable devices. Many devices in the IoT need sustained energy with a higher voltage requirement than currently available in photovoltaic devices. Conventional photovoltaic devices usually provide voltages of less than 1 volt to about less than about 1.8 volts. This is insufficient for many applications. Traditional high voltage solutions include attaching multiple cells laterally and connecting the cells in series or tandem cells. However, these solutions may not provide the voltage potentials needed to proficiently run many device operations.

### SUMMARY

In accordance with an embodiment of the present invention, a photovoltaic device includes a substrate and a P-type layer having a first electrode formed on a surface of the P-type layer. An N-type layer has a second electrode formed on a surface of the N-type layer. The P-type layer and the N-type are formed from a common base material. The base material includes a bandgap of at least 2 electron-volts such that a potential across the first and second electrodes is greater than 2 volts when the device is exposed to light.

Another photovoltaic device includes a substrate, a P-type layer having a first electrode formed on a surface of the P-type layer and an N-type layer having a second electrode formed on a surface of the N-type layer. The P-type layer and the N-type are formed from a common base material. The base material includes a bandgap of at least 2 electron-volts. A communication system is coupled to the first and second electrodes to draw power greater than 2 volts from the first and second electrodes, when the device is exposed to light, to perform a communication function.

Yet another photovoltaic powered device includes a communication system configured to communicate with a network; a processor coupled to the communication system and memory coupled to the processor. At least one photovoltaic cell is configured to power the communication system, the processor and the memory by providing power of greater than 2 volts, when the device is exposed to light. The at least one photovoltaic cell includes a substrate, a P-type layer having a first electrode formed on a surface of the P-type layer and an N-type layer having a second electrode formed on a surface of the N-type layer, the P-type layer and the N-type being formed from a common base material, the base material including a bandgap of at least 2 electron-volts.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view showing a single cell photovoltaic device employing high bandgap materials to generate a high voltage across electrodes in accordance with an embodiment of the present invention;

FIG. 2 is a cross-sectional view showing a single cell photovoltaic device having an intrinsic layer disposed between N-type and P-type layers and employing high bandgap materials to generate a high voltage across electrodes in accordance with an embodiment of the present invention; and

FIG. 3 is a block/flow diagram showing a system powered by a high voltage photovoltaic device in accordance with an embodiment of the present invention.

### DETAILED DESCRIPTION

In accordance with embodiments of the present invention, photovoltaic devices are provided that employ wide bandgap semiconductor materials that are activated using short wavelength laser light or other portions of the electromagnetic spectrum to deliver high voltage using a single photovoltaic cell. While tandem cells may be employed, the single photovoltaic cell provides ease of manufacture and ease of incorporation into other devices and systems. In particularly useful embodiments, materials employed for the high voltage photovoltaic devices can include materials having bandgaps greater than about 2 eV. These high bandgap materials are considered inefficient for photovoltaic device use due at least to the high barrier energy to be overcome to cause conduction.

The high voltage photovoltaic devices can be made having small sizes, e.g., less than about 100 microns, to fit in or on electronic devices. The high voltage photovoltaic devices can provide output voltage ranges from about 2 volts to about 6 volts from a single junction photovoltaic device. Higher voltages can be obtained in multi-junction devices.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

A design for a photovoltaic device may be created for integrated circuit integration or may be combined with components on a printed circuit board. The circuit/board may be embodied in a graphical computer programming language, and stored in a computer storage medium (such as a disk, tape, physical hard drive, or virtual hard drive such as in a storage access network). If the designer does not fabricate chips or the photolithographic masks used to fabricate chips or photovoltaic devices, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of photovoltaic devices and/or integrated circuit chips with photovoltaic devices. The resulting devices/chips can be distributed by the fabricator in raw wafer form (that is, as a single wafer that has multiple unpackaged devices/chips), as a bare die, or in a packaged form. In the latter case the device/chip is mounted in a single chip package (such as a plastic carrier, with leads that are affixed to a motherboard or other higher level carrier) or in a multichip package (such as a ceramic carrier that has either or both surface interconnections or buried interconnections). In any case, the devices/chips are then integrated with other chips, discrete circuit elements, and/or other signal processing devices as part of either (a) an intermediate product, such as a motherboard, or (b) an end product. The end product can be any product that includes integrated circuit chips, ranging from toys, energy collectors, solar devices and other applications including computer products or devices having a display, a keyboard or other input device, and a central processor. The photovoltaic devices described herein are particularly useful for solar cells or panels employed to provide power to electronic devices, homes, buildings, vehicles, etc.

It should also be understood that material compounds will be described in terms of listed elements, e.g., InGaN, InGaAs or SiGe. These compounds can include different proportions of the elements within the compound, e.g., InGaAs includes Inₓ,Ga₁₋ₓAs, where x is less than or equal to 1, or SiGe includes SiₓGe₁₋ₓ where x is less than or equal to 1, etc. In addition, other elements may be included in the compound, such as, e.g., AlInGaAs, and still function in accordance with the present embodiments. The compounds with additional elements will be referred to herein as alloys.

The present embodiments may be part of a photovoltaic device or circuit, and the circuits as described herein may be part of a design for an integrated circuit chip, a solar cell, a light sensitive device, etc. The photovoltaic device may be a device for use in calculators, solar powered lights, IoT applications, etc.

It is also to be understood that the present invention may be described in terms of a particular tandem (multi-junction) structure. The tandem structure can include cells, which will be described in terms of a particular material. Each cell includes a p-doped layer, an n-doped layer and perhaps an undoped intrinsic layer. For the present description, the n-doped layer and p-doped layers will be formed either from a same base material that is doped to provide an n-type portion and a p-type portion or from two different base materials so that a first material is doped to provide the n-type portion and the second material is doped to provide the p-type portion. For simplicity, each cell layer can be described in terms of the base layer material. The n-doped and p-doped regions are preferably formed by doping during epitaxial growth. Other doping methods may also be employed. Intrinsic layers may be formed between the n-type and p-type layers.

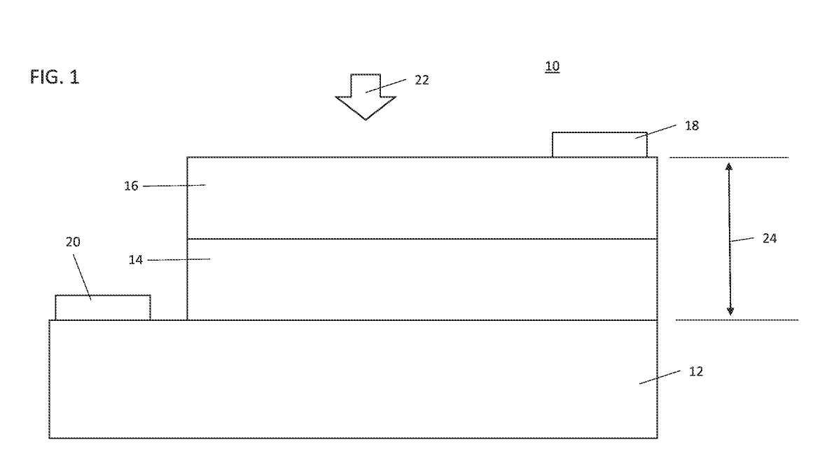

Referring now to the drawings in which like numerals represent the same or similar elements and initially to FIG. 1, a first high voltage photovoltaic device structure 10 is illustratively shown. The high voltage photovoltaic device structure 10 may include a plurality of different material combinations, which may be used with different incident light wavelengths to output a high voltage. In one aspect, structure 10 includes a substrate 12, an N-type layer 14, a P-type layer 16 and electrodes 18 and 20.

It should be understood that the high voltage referred to herein is relative to conventional photovoltaic cells. High voltage refers to output voltages or open circuit voltages of greater than about 2 volts.

The structure 10 can include monocrystalline layers which may be deposited by epitaxial growth. Depending on the application, amorphous materials, nanocrystalline, microcrystalline and polycrystalline materials can also be formed.

The electrodes 18 and 20 may include any suitable conductor such as, a transparent conductor, e.g., zinc oxide (ZnO), indium tin oxide (ITO), indium zinc oxide (IZO), etc.; a metal (e.g., tungsten, titanium, tantalum, ruthenium, zirconium, cobalt, copper, aluminum, lead, platinum, tin, silver, gold); a conducting metallic compound material (e.g., tantalum nitride, titanium nitride, tungsten silicide, tungsten nitride, ruthenium oxide, cobalt silicide, nickel silicide); a carbon nanotube; conductive carbon; graphene, or any suitable combination of these materials. The conductive material may further comprise dopants that are incorporated during or after deposition.

In some embodiments, the P-type layer 16 and the N-type layer 14 can be reversed in order relative to the substrate 12. Light 22 falls incident on the top layer (P-type layer 16 in this instance). The structure 10 can include an area of about 100 by 100 microns or less, although other sizes are contemplated. The P-type layer 16 and the N-type layer 14 may have a thickness 24 of about one micron in thickness. Other thicknesses may be employed.

In one embodiment, the structure 10 includes wide bandgap materials including GaN (or InGaN). In this embodiment, the P-type layer 16 includes P-GaN, and the N-type layer 14 includes N-GaN. The substrate 12 may include N-GaN, as well. In this embodiment, light 22 may include blue light (e.g., wavelengths less than about 380 nm) to generate a voltage across electrodes 18, 20 of about 2.7 volts.

In another embodiment, the structure 10 includes wide bandgap materials including GaN. In this embodiment, the P-type layer 16 includes P-GaN, and the N-type layer 14 includes N-GaN. The substrate 12 may include sapphire. In this embodiment, light 22 may include blue light (e.g., wavelengths less than about 380 nm) to generate a voltage across electrodes 18, 20 of about 2.7 volts.

In yet another embodiment, the structure 10 includes wide bandgap materials including GaN. In this embodiment, the P-type layer 16 includes P-GaN, and the N-type layer 14 includes N-GaN. The substrate 12 may include Si or Si based materials (e.g., SiGe, SiC, etc.). In this embodiment, light 22 may include blue light (e.g., wavelengths less than about 380 nm) to generate a voltage across electrodes 18, 20 of about 2.7 volts.

In still another embodiment, the structure 10 includes wide bandgap materials including AlGaN. In this embodiment, the P-type layer 16 includes P-AlGaN, and the N-type layer 14 includes N-AlGaN. The substrate 12 may include N-GaN. In this embodiment, light 22 may include ultraviolet light (e.g., wavelengths less than about 450 nm) to generate a voltage across electrodes 18, 20 of between about 2.7 volts and about 5 volts.

In still another embodiment, the structure 10 includes wide bandgap materials including AlGaN. In this embodiment, the P-type layer 16 includes P-AlGaN, and the N-type layer 14 includes N-AlGaN. The substrate 12 may include a sapphire substrate. In this embodiment, light 22 may include ultraviolet light (e.g., wavelengths less than about 450 nm) to generate a voltage across electrodes 18, 20 of between about 2.7 volts and about 5 volts.

In still another embodiment, the structure 10 includes wide bandgap materials including AlGaN. In this embodiment, the P-type layer 16 includes P-AlGaN, and the N-type layer 14 includes N-AlGaN. The substrate 12 may include Si or Si based materials (e.g., SiGe, SiC, etc.). In this embodiment, light 22 may include ultraviolet light (e.g., wavelengths less than about 450 nm) to generate a voltage across electrodes 18, 20 of between about 2.7 volts and about 5 volts.

In still another embodiment, the structure 10 includes wide bandgap materials including AlN. In this embodiment, the P-type layer 16 includes P-AlN, and the N-type layer 14 includes N-AlN. The substrate 12 may include an AlN substrate. In this embodiment, light 22 may include wavelengths less than about 280 nm to generate a voltage across electrodes 18, 20 of about 5.7 volts.

In still another embodiment, the structure 10 includes wide bandgap materials including AlN. In this embodiment, the P-type layer 16 includes P-AlN, and the N-type layer 14 includes N-AlN. The substrate 12 may include a sapphire substrate. In this embodiment, light 22 may include wavelengths less than about 280 nm to generate a voltage across electrodes 18, 20 of about 5.7 volts.

In still another embodiment, the structure 10 includes wide bandgap materials including AlN. In this embodiment, the P-type layer 16 includes P-AlN, and the N-type layer 14 includes N-AlN. The substrate 12 may include Si or Si based materials (e.g., SiGe, SiC, etc.). In this embodiment, light 22 may include wavelengths less than about 280 nm to generate a voltage across electrodes 18, 20 of about 5.7 volts.

In still another embodiment, the structure 10 includes wide bandgap materials including SiC. In this embodiment, the P-type layer 16 includes P-SiC, and the N-type layer 14 includes N-SiC. The substrate 12 may include SiC. In this embodiment, light 22 may include wavelengths less than about 400 nm to generate a voltage across electrodes 18, 20 of between 2-6 volts.

In still another embodiment, the structure 10 includes wide bandgap materials including GaP. In this embodiment, the P-type layer 16 includes P-GaP, and the N-type layer 14 includes N-GaP. The substrate 12 may include GaP. In this embodiment, light 22 may include wavelengths less than about 450 nm to generate a voltage across electrodes 18, 20 of between 2-6 volts.

In still another embodiment, the structure 10 includes wide bandgap materials including GaP. In this embodiment, the P-type layer 16 includes P-GaP, and the N-type layer 14 includes N-GaP. The substrate 12 may include Si or Si based materials (e.g., SiGe, SiC, etc.). In this embodiment, light 22 may include wavelengths less than about 450 nm to generate a voltage across electrodes 18, 20 of between 2-6 volts.

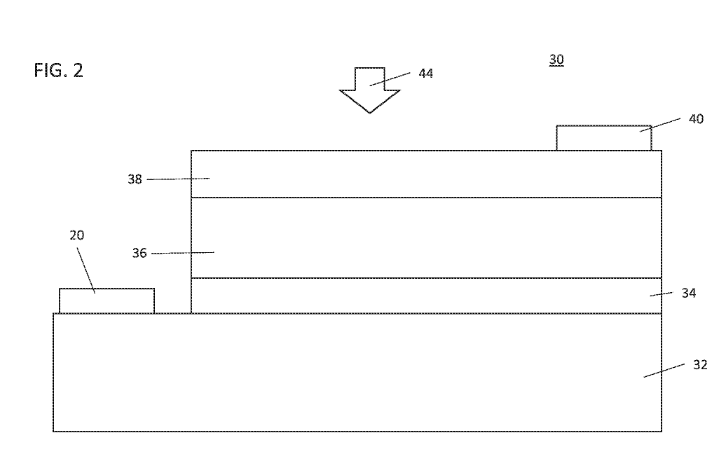

Referring to FIG. 2, a second high voltage photovoltaic device structure 30 is illustratively shown. The high voltage photovoltaic device structure 30 may include a plurality of different material combinations, which may be used with different incident light wavelengths to output a high voltage. In one aspect, structure 30 includes a substrate 32, an N-type layer 34, an intrinsic layer 36, a P-type layer 38 and electrodes 40 and 42.

The structure 30 can include monocrystalline layers which may be deposited by epitaxial growth. Depending on the application, amorphous materials, nanocrystalline, microcrystalline and polycrystalline materials can also be formed.

The electrodes 40 and 42 may include any suitable conductor such as, a transparent conductor, e.g., ZnO, ITO, IZO, etc.; a metal (e.g., tungsten, titanium, tantalum, ruthenium, zirconium, cobalt, copper, aluminum, lead, platinum, tin, silver, gold); a conducting metallic compound material (e.g., tantalum nitride, titanium nitride, tungsten silicide, tungsten nitride, ruthenium oxide, cobalt silicide, nickel silicide); a carbon nanotube; conductive carbon; graphene, or any suitable combination of these materials. The conductive material may further comprise dopants that are incorporated during or after deposition.

In some embodiments, the P-type layer 38 and the N-type layer 34 can be reversed in order relative to the substrate 32. Light 44 falls incident on the top layer (P-type layer 38 in this instance). The structure 30 may include an area of about 100 by 100 microns or less. The P-type layer 38 and the N-type layer 34 may have a thickness of about one micron in thickness. Other thicknesses may be employed.

In one embodiment, the structure 30 includes wide bandgap materials including GaN. In this embodiment, the P-type layer 38 includes P-GaN, the intrinsic layer 36 includes intrinsic InGaN, and the N-type layer 34 includes N-GaN. The substrate 32 may include GaN, sapphire or Si. In this embodiment, light 44 may include wavelengths less than about 380 nm to generate a voltage across electrodes 40, 42 of about 2.7 volts.

In another embodiment, the structure 30 includes wide bandgap materials including GaN. In this embodiment, the P-type layer 38 includes P-GaN, the intrinsic layer 36 includes alternating layers of intrinsic InGaN and GaN in a multiple quantum well (MQW) structure, and the N-type layer 34 includes N-GaN. The substrate 32 may include GaN, sapphire or Si. In this embodiment, light 44 may include wavelengths less than about 380 nm to generate a voltage across electrodes 40, 42 of about 2.7 volts.

In yet another embodiment, the structure 30 includes wide bandgap materials including AlGaN. In this embodiment, the P-type layer 38 includes P-AlGaN, the intrinsic layer 36 includes intrinsic GaN, and the N-type layer 34 includes N-AlGaN. The substrate 32 may include N-GaN, sapphire or Si. In this embodiment, light 44 may include wavelengths less than about 450 nm to generate a voltage across electrodes 40, 42 of about 2.7 volts to about 5 volts.

In still another embodiment, the structure 30 includes wide bandgap materials including AlGaN. In this embodiment, the P-type layer 38 includes P-AlGaN, the intrinsic layer 36 includes alternating layers of intrinsic GaN and AlGaN in a MQW structure, and the N-type layer 34 includes N-AlGaN. The substrate 32 may include N-GaN, sapphire or Si. In this embodiment, light 44 may include wavelengths less than about 450 nm to generate a voltage across electrodes 40, 42 of about 2.7 volts to about 5 volts.

In still another embodiment, the structure 30 includes wide bandgap materials including AlN. In this embodiment, the P-type layer 38 includes P-AlN, the intrinsic layer 36 includes intrinsic AlGaN, and the N-type layer 34 includes N-AlN. The substrate 32 may include AlN, sapphire or Si. In this embodiment, light 44 may include wavelengths less than about 280 nm to generate a voltage across electrodes 40, 42 of about 5.7 volts.

In still another embodiment, the structure 30 includes wide bandgap materials including AlN. In this embodiment, the P-type layer 38 includes P-AlN, the intrinsic layer 36 includes alternating layers of intrinsic AlGaN and AlN in a MQW structure and the N-type layer 34 includes N-AlN. The substrate 32 may include AlN, sapphire or Si. In this embodiment, light 44 may include wavelengths less than about 280 nm to generate a voltage across electrodes 40, 42 of about 5.7 volts.

It should be understood that combinations of the cells described in FIGS. 1 and 2 may be combined in a tandem cell arrangement of two or more cells stacked on one another. The tandem cells or multi-junction cells may result in increased efficiency or may be arranged to increase the voltage across electrodes.

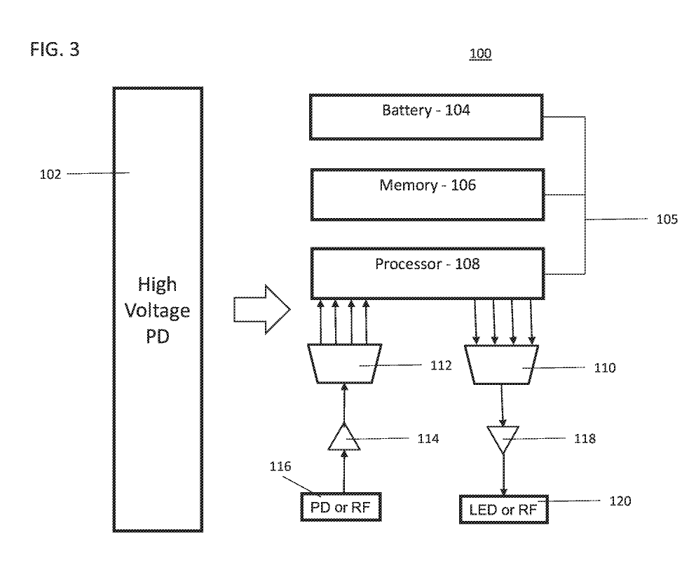

Referring to FIG. 3, an illustrative system 100 shows an exemplary IoT application employing a high voltage photovoltaic device 102 in accordance with aspects of the present invention. The system 100 includes a processor 108, memory 106 coupled to the processor 108 and a battery 104 for backup or energizing the system 100. The processor 108, memory 106 and the battery 104 can be powered by the high voltage photovoltaic device 102, in part or in full.

The processor 108 can include a computer processing unit (CPU) operatively coupled to other components via a system bus. The memory 106 may include a Read Only Memory (ROM), a Random Access Memory (RAM), an input/output (I/O) adapter, a network adapter, a user interface adapter, and a display adapter, etc. which can be operatively coupled to a system bus 105.

The system 100 may include a radiofrequency (RF) or light (e.g., infrared (IR)) communication system. The communication system includes a receiver 116 that can include a photodiode (PD) or RF antenna. The received signal can be amplified by an amplifier 114 powered by the high voltage photovoltaic device 102. The received signal can be demultiplexed by a demultiplexer 112, which may be powered by the high voltage photovoltaic device 102. The communication system includes a transmitter 120 that can include a light emitting diode (LED) or RF antenna. The transmitted signal can be amplified by an amplifier 118 powered by the high voltage photovoltaic device 102. The transmitted signal can be multiplexed by a multiplexer 110, which may be powered by the high voltage photovoltaic device 102.

The received and transmitted signals may be processed by the processor 108. The processor 108 may encrypt/decrypt the signals, run programs stored in the memory 106, store data in the memory 106 and perform other functions and operations. The system 100 can be deployed in a remote location and rely solely on energy provided by the high voltage photovoltaic device 102. In some embodiments, multiple high voltage photovoltaic devices 102 may be employed. The energy provided by the high voltage photovoltaic device 102 may be coupled to devices that consume the energy.

In useful embodiments, incident light may include sunlight or may be provided using other devices to create, e.g., blue light and UV light. Light components, such as an LED or laser may be employed to power the photovoltaic device 102. In one embodiment, laser light can be directed on the high voltage photovoltaic device 102. The laser or LED may itself be powered by one or more conventional photovoltaic devices. Alternately, the laser or LED may be powered by a rechargeable battery (104).

In other embodiments, a low voltage photovoltaic device or other device may be employed to power an LED, laser, lamp or fiber optic coupled light to provide a desirable wavelength to enable the high voltage photovoltaic device 102 to output a high voltage. In accordance with aspects of the present invention, LEDs (120) can be driven for communication applications (e.g., 2˜3V are needed). In other embodiments, memory cells (106) can be written to or read from (e.g., 2˜3.5V are needed). The battery (104) can be charged in accordance with useful embodiments (e.g., ˜3.5V are needed). The processor (106) can be operated in accordance with useful embodiments (e.g., ˜3.5V−˜5V are needed), etc.

While tandem cells may be employed in accordance with aspects of the present invention, in preferred embodiments, a single photovoltaic cell may be employed to generate the high voltage potentials. The single photovoltaic cell reduces operational and manufacturing complexity, and limits size constraints (e.g., less than about 100 square microns), among other things. In accordance with some embodiments, a single photovoltaic cell cab provide, e.g., an output voltage between about 2 V and about 6 V. The output voltage can be greater in a tandem cell arrangement.

In some alternative implementations, the functions noted in the blocks may occur out of the order noted in the figures. For example, two blocks shown in succession may, in fact, be executed or placed together, or the blocks may sometimes be executed or placed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments for high voltage photovoltaics (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A photovoltaic device, comprising:
a substrate;
a P-type layer having a first electrode formed on a surface of the P-type layer; and
an N-type layer directly on a first surface of the substrate and having a second electrode directly on the first surface of the substrate with the N-type layer separated from the second electrode, the P-type layer and the N-type being formed from a common base material, the base material including a bandgap of at least 2 electron-volts such that a potential across the first and second electrodes is greater than 2.7 Volts when the device is exposed to light.

2. The device as recited in claim 1, wherein the substrate includes a material selected from the group consisting of Si, sapphire, AlN and GaN.

3. The device as recited in claim 1, wherein the P-type layer and the N-type layer include a material selected from the group consisting of AlGaN, and AlN.

4. The device as recited in claim 1, wherein the P-type layer and the N-type layer include SiC on a SiC substrate.

5. The device as recited in claim 1, wherein the P-type layer and the N-type layer include AlN on a GaN substrate.

6. The device as recited in claim 1, wherein the P-type layer and the N-type layer include GaP on a GaP substrate.

7. The device as recited in claim 1, further comprising an intrinsic layer disposed between the N-type layer and the P-type layer.

8. The device as recited in claim 7, wherein the intrinsic layer includes a multiple quantum well structure.

9. The device as recited in claim 7, wherein the intrinsic layer includes a single intrinsic compound.

10. A photovoltaic device, comprising:
a substrate;
a P-type layer having a first electrode formed on a surface of the P-type layer;
an N-type layer directly on a first surface of the substrate and having a second electrode directly on the first surface of the substrate with the N-type layer separated from the second electrode, the P-type layer and the N-type being formed from a common base material, the base material including a bandgap of at least 2 electron-volts; and
a communication system coupled to the first and second electrodes to draw power greater than 2.7 volts from the first and second electrodes, when the device is exposed to light, to perform a communication function.

11. The device as recited in claim 10, wherein the substrate includes a material selected from the group consisting of Si, sapphire, AlN and GaN.

12. The device as recited in claim 10, wherein the P-type layer and the N-type layer include a material selected from the group consisting of AlGaN, InGaN and AlN.

13. The device as recited in claim 10, wherein the P-type layer and the N-type layer include SiC on a SiC substrate.

14. The device as recited in claim 10, wherein the P-type layer and the N-type layer include AlN on a GaN substrate.

15. The device as recited in claim 10, wherein the P-type layer and the N-type layer include GaP on a GaP substrate.

16. The device as recited in claim 10, further comprising an intrinsic layer disposed between the N-type layer and the P-type layer.

17. (canceled)

18. A photovoltaic powered device, comprising:
a communication system configured to communicate with a network;
a processor coupled to the communication system;
memory coupled to the processor; and
at least one photovoltaic cell configured to power the communication system, the processor and the memory by providing power of greater than 2 volts, when the device is exposed to light, including:
a substrate;
a P-type layer having a first electrode formed on a surface of the P-type layer; and
an N-type layer directly on a first surface of the substrate and having a second electrode directly on the first surface of the substrate with the N-type layer separated from the second electrode, the P-type layer and the N-type being formed from a common base material, the base material including a bandgap of at least 2 electron-volts,
wherein the P-type layer is directly on the N-type layer.

19. The device as recited in claim 18, wherein the substrate includes a material selected from the group consisting of Si, sapphire, AlN and GaN and the common base material includes a material selected from the group consisting of GaN, AlGaN, InGaN and AlN.

20. The device as recited in claim 18, wherein the P-type layer and the N-type layer include one of SiC on a SiC substrate, AlN on a GaN substrate or GaP on a GaP substrate.

21. The device as recited in claim 1, wherein the surface of the P-type layer is less than 100 microns by 100 microns.
